(19) United States
(12) Patent Application Publication
(10) Pub. No.: US 2017/0315244 A1
(43) Pub. Date: Nov. 2, 2017

(54) DETECTION DEVICE

(71) Applicant: Sharp Kabushiki Kaisha, Sakai City, Osaka (JP)

(72) Inventors: KAZUATSU ITO, Sakai City (JP); SHIGEYASU MORI, Sakai City (JP); TADAYOSHI MIYAMOTO, Sakai City (JP); KAORU YAMAMOTO, Sakai City (JP)

(21) Appl. No.: 15/528,102

(22) PCT Filed: Nov. 16, 2015
(86) PCT No.: PCT/JP2015/082147

§ 371 Date: May 19, 2017

(30) Foreign Application Priority Data
Nov. 21, 2014 (JP) 2014-236842

(51) Int. Cl. G01T 1/24; H01L 31/02; H01L 31/032; H01L 31/119

(52) U.S. Cl. CPC G01T 1/24; H01L 31/119; H01L 31/02019; H01L 31/032

(57) ABSTRACT

The invention provides a detection device including a fewer types of elements for detection of radial rays and configured to appropriately detect the radial rays. A detection device 1 includes a light source 30 configured to emit radial rays, a detection circuit board 10 provided with a plurality of detection circuits each configured to output a signal according to a control signal supplied from a driving circuit 201, and a signal reading circuit 202 configured to acquire the signals outputted from the plurality of detection circuits. The detection circuits each include a detection thin film transistor having threshold voltage varied in accordance with irradiation of the radial rays. The signal reading circuit 202 transmits, to an image processing device 40, a difference between a signal outputted from each of the detection circuits in accordance with a control signal supplied before irradiation of the radial rays and a signal outputted from the detection circuit in accordance with a control signal supplied after irradiation of the radial rays.

### TECHNICAL FIELD

The present invention relates to a detection device configured to detect radial rays like X-rays.

### BACKGROUND ART

A known X-ray imaging device includes an imaging panel provided with a plurality of pixels and configured to capture an X-ray image. According to a technique disclosed in JP 2006-165530 A, pixels each includes a thin film transistor (TFT), a photodiode, and a scintillator. The scintillator converts X-rays having been transmitted through a target to visible rays, the photodiode converts the visible rays to electric charges, and the TFT is actuated to read the electric charges stored in each of the pixels.

### DISCLOSURE OF INVENTION

The configuration including the scintillators and the photodiodes as in JP 2006-165530 A needs a step of forming elements such as the scintillators and the photodiodes in addition to the TFTs in a process of producing an imaging panel. Furthermore, the configuration including the scintillators may have deterioration in spatial resolution due to scattered scintillation light and thus have deterioration in quality of a captured X-ray image.

It is an object of the present invention to provide a detection device including a fewer elements for detection of radial rays like X-rays and configured to appropriately detect the radial rays.

A detection device according to the present invention includes: an irradiation unit configured to emit radial rays; a driving unit configured to output a control signal; a detection circuit configured to output a signal according to the control signal; and a signal processor configured to acquire the signal outputted from the detection circuit; in which the detection circuit includes a detection thin film transistor having threshold voltage varied in accordance with irradiation of the radial rays, and the signal processor outputs a difference between a signal outputted from the detection circuit in accordance with a control signal supplied before irradiation of the radial rays and a signal outputted from the detection circuit in accordance with a control signal supplied after irradiation of the radial rays.

The configuration according to the present invention includes such a fewer elements for detection of radial rays and is configured to appropriately detect the radial rays.

### BRIEF DESCRIPTION OF DRAWINGS

FIG. 1 is a schematic diagram illustrating an exemplary configuration of a detection device according to a first embodiment.

FIG. 2 is a schematic diagram of a detection circuit board, a driving circuit, and a signal reading circuit illustrated in FIG. 1.

FIG. 3 is an equivalent circuit diagram of a detection circuit provided in each pixel illustrated in FIG. 2.

FIG. 4A is a graph indicating a threshold voltage property of a TFT 122 illustrated in FIG. 3.

FIG. 4B is a graph indicating a threshold voltage property of TFTs other than the TFT 122 illustrated in FIG. 3.

FIG. 4C is a graph indicating a relation between an X-ray irradiation dose and a threshold voltage shift amount.

FIG. 5 is a timing chart of control signals supplied to the detection circuit in one frame period.

FIG. 6A is a timing chart indicating an X-ray irradiation period.

FIG. 6B is a timing chart indicating potential at a node Va of the detection circuit illustrated in FIG. 3 and read periods for voltage signals from the detection circuit.

FIG. 7A is a schematic top view of the TFT 122 illustrated in FIG. 3.

FIG. 7B is a schematic top view of a TFT 121 illustrated in FIG. 3.

FIG. 8A is a sectional view taken along line A-A, of the TFT illustrated in FIG. 7A.

FIG. 8B is a sectional view taken along line A-A, of the TFT illustrated in FIG. 7B.

FIG. 9A is a sectional view illustrating a production process of forming gate electrodes of the TFTs on a substrate illustrated in FIGS. 8A and 8B.

FIG. 9B is a sectional view illustrating a production process of forming a gate insulating film on the gate electrodes of the TFTs illustrated in FIG. 9A.

FIG. 9C is a sectional view illustrating a production process of forming semiconductor layers on the gate insulating film of the TFTs illustrated in FIG. 9B.

FIG. 9D is a sectional view illustrating a production process of forming source layers on the semiconductor layers illustrated in FIG. 9C.

FIG. 9E is a sectional view illustrating a production process of forming a passivation film on the semiconductor layers illustrated in FIG. 9D.

FIG. 9F is a sectional view illustrating a production process of forming a flattening film on the passivation film illustrated in FIG. 9E.

FIG. 10A is a sectional view illustrating a configuration of a TFT 122 according to a second embodiment.

FIG. 10B is a sectional view illustrating a configuration of a TFT 121 according to the second embodiment.

FIG. 11A is a sectional view illustrating a production process of forming a gate insulating film on gate electrodes of the TFTs illustrated in FIG. 10.

FIG. 11B is a sectional view illustrating a production process of thinning the gate insulating film on the TFT 121 illustrated in FIG. 11A.

FIG. 12 is a graph indicating a relation between a TFT channel length and a threshold voltage shift amount.

FIG. 13 is an equivalent circuit diagram of a detection circuit according to a modification example 5.

FIG. 14 is a schematic diagram of a detection circuit board, a driving circuit, and a signal reading circuit according to the modification example 5.

FIG. 15 is a timing chart indicating control signals supplied to the detection circuit illustrated in FIG. 13 in one frame period and an X-ray irradiation period.

### DESCRIPTION OF EMBODIMENTS

A detection device according to an embodiment of the present invention includes: an irradiation unit configured to emit radial rays; a driving unit configured to output a control signal; a detection circuit configured to output a signal according to the control signal; and a signal processor configured to acquire the signal outputted from the detection circuit; in which the detection circuit includes a detection thin film transistor having threshold voltage varied in accordance with irradiation of the radial rays, and the signal processor outputs a difference between a signal outputted from the detection circuit in accordance with a control signal supplied before irradiation of the radial rays and a signal outputted from the detection circuit in accordance with a control signal supplied after irradiation of the radial rays (a first configuration).

In the detection device according to the first configuration, the driving unit transmits the control signal to the detection circuit, and the detection circuit outputs the signal according to the control signal. The detection circuit includes the detection thin film transistor having the threshold voltage varied in accordance with irradiation of the radial rays. The signal processor outputs the difference between the signal outputted from the detection circuit in accordance with the control signal supplied from the irradiation unit before irradiation of the radial rays and the signal outputted from the detection circuit in accordance with the control signal supplied after irradiation of the radial rays. Irradiation of the radial rays changes the threshold voltage of the detection thin film transistor, to change the signals outputted from the detection circuit between before and after irradiation of the radial rays. Obtaining the difference between the signals outputted from the detection circuit before and after irradiation of the radial rays enables appropriate detection of the radial rays without use of any element other than the thin film transistor.

According to a second configuration, the radial rays in the first configuration can be X-rays.

The second configuration enables detection of the X-rays without use of any element such as a scintillator or a photodiode, and thus achieves reduction in cost and time for production of the detection device.

According to a third configuration, in the first or second configuration, optionally, the detection circuit further includes a driving thin film transistor having threshold voltage varied by irradiation of the radial rays more slightly than the detection thin film transistor, the detection thin film transistor and the driving thin film transistor each include a semiconductor layer, and the semiconductor layer in the detection thin film transistor is larger in area than the semiconductor layer in the driving thin film transistor.

The larger semiconductor layer leads to more influence by the radial rays in the third configuration, to achieve easier variation in threshold voltage of the detection thin film transistor than the driving thin film transistor. Furthermore, the detection thin film transistor and the driving thin film transistor can be produced in an identical production process to achieve reduction in cost and time for production.

According to a fourth configuration, in any one of the first to third configurations, optionally, the detection circuit further includes a driving thin film transistor having threshold voltage varied by irradiation of the radial rays more slightly than the detection thin film transistor, the detection thin film transistor and the driving thin film transistor each include a gate electrode, an insulating film covering the gate electrode and including an oxide film, and a semiconductor layer provided on the insulating film, and the oxide film included in the insulating film of the detection thin film transistor is thicker than the oxide film included in the insulating film of the driving thin film transistor.

The thicker oxide film in the insulating film leads to more influence by the radial rays in the fourth configuration, to achieve easier variation in threshold voltage of the detection thin film transistor than the driving thin film transistor. Furthermore, the detection thin film transistor and the driving thin film transistor can be produced in an identical production process to achieve reduction in cost and time for production.

According to a fifth configuration, in any one of the first to fourth configurations, optionally, the detection circuit further includes a driving thin film transistor having threshold voltage varied by irradiation of the radial rays more slightly than the detection thin film transistor, the detection thin film transistor and the driving thin film transistor each include a semiconductor layer, and the semiconductor layer in the detection thin film transistor is thicker than the semiconductor layer in a thin film transistor other than the detection thin film transistor.

The thicker semiconductor layer leads to more influence by the radial rays in the fifth configuration, to achieve easier variation in threshold voltage of the detection thin film transistor than the other thin film transistor. Furthermore, the detection thin film transistor and the other thin film transistor can be produced in an identical production process to achieve reduction in cost and time for production.

According to a sixth configuration, in any one of the first to fifth configurations, optionally, the detection circuit further includes a driving thin film transistor having threshold voltage varied by irradiation of the radial rays more slightly than the detection thin film transistor, and the detection thin film transistor is larger in channel length than the driving thin film transistor.

The larger channel length leads to more influence by the radial rays in the sixth configuration, to achieve easier variation in threshold voltage of the detection thin film transistor than the driving thin film transistor. Furthermore, the detection thin film transistor and the driving thin film transistor can be produced in an identical production process to achieve reduction in cost and time for production.

According to a seventh configuration, in any one of the first to sixth configurations, optionally, the detection circuit further includes a driving thin film transistor having threshold voltage varied by irradiation of the radial rays more slightly than the detection thin film transistor, and the detection thin film transistor includes a semiconductor layer containing low-temperature polysilicon, and the driving thin film transistor includes a semiconductor layer containing an oxide.

The semiconductor layer containing low-temperature polysilicon lead to more influence by the radial rays than the semiconductor layer containing the oxide in the seventh configuration, to achieve easier variation in threshold voltage of the detection thin film transistor than the driving thin film transistor.

Embodiments of the present invention will be described in detail below with reference to the drawings. Identical or corresponding portions in the drawings will be denoted by identical reference signs and will not be described repeatedly.

### First Embodiment

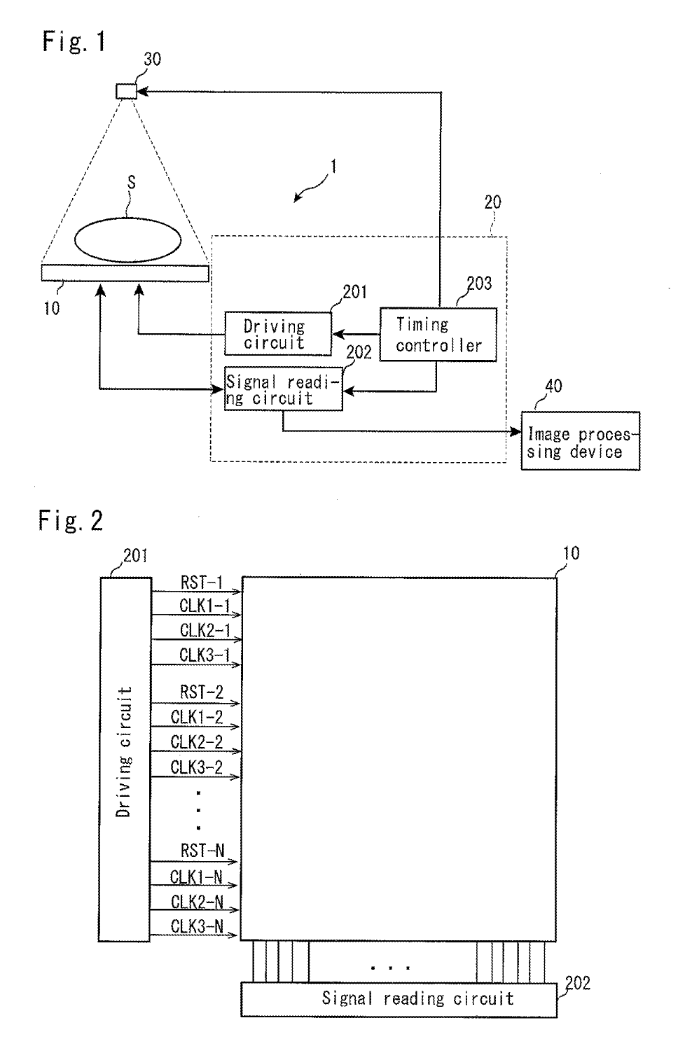

A detection device according to the first embodiment of the present invention is an X-ray detection device configured to detect X-rays applied to a target. FIG. 1 is a schematic diagram of the detection device according to the present embodiment. A detection device 1 includes a detection circuit board 10, a control unit 20, and a light source 30.

In the detection device 1 under the control of the control unit 20, the light source 30 irradiates a target S with X-rays exemplifying radial rays at predetermined timing, the detection circuit board 10 detects X-rays having been transmitted through the target S and transmits an image signal indicating a detection result to an image processing device 40. The image processing device 40 generates an X-ray image in accordance with the image signal. Configurations of the respective portions will be described below.

As illustrated in FIG. 1, the control unit 20 includes a driving circuit 201, a signal reading circuit 202, and a timing controller 203. The driving circuit 201 is electrically connected with the timing controller 203 and the detection circuit board 10. Under the control of the timing controller 203, the driving circuit 201 supplies the detection circuit board 10 with a control signal for driving each detection circuit provided at the detection circuit board 10.

The signal reading circuit 202 is electrically connected with the timing controller 203 and the detection circuit board 10. Under the control of the timing controller 203, the signal reading circuit 202 generates an image signal in accordance with the detection result outputted from the detection circuit board 10, and transmits the image signal to the image processing device 40.

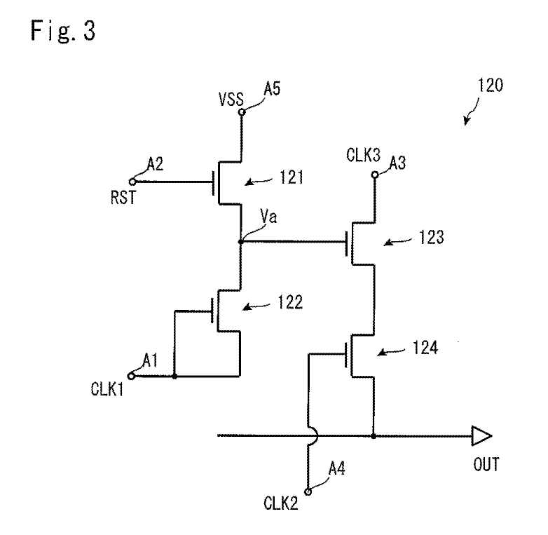

FIG. 2 is a schematic diagram of the detection circuit board 10, the driving circuit 201, and the signal reading circuit 202. The detection circuit board 10 is provided with a plurality of detection circuits (not illustrated in FIG. 2). The detection circuit board 10 is further provided with driving lines (not illustrated) connected with the driving circuit 201, for supply of a control signal outputted from the driving circuit 201 to each of the detection circuits. The detection circuit board 10 is also provided with signal read lines (not illustrated) connected with the signal reading circuit 202, for reading of a signal from each of the detection circuits. The driving lines and the signal read lines are disposed perpendicular to each other at the detection circuit board 10.

The driving lines connected to each of the detection circuits at the detection circuit board 10 include four lines in total, namely, one reset signal line and three clock signal lines (a first clock signal line, a second clock signal line, and a third clock signal line). The reset signal line receives a reset signal RST from the driving circuit 201. The first clock signal line receives a first clock signal CLK1 from the driving circuit 201. The second clock signal line receives a second clock signal CLK2 from the driving circuit 201. The third clock signal line receives a third clock signal CLK3 from the driving circuit 201. The respective control signals will be described in detail later.

The detection circuit board 10 has regions each provided with one of the detection circuits and each corresponding to a pixel of the X-ray image generated by the image processing device 40. The region provided with each of the detection circuits will be referred to as a pixel in the following description. Assume that the detection circuit board 10 has pixels of N (N is an integer not less than one) rows and M (M is an integer not less than one) columns. In the following description, the reset signal RST, the first clock signal CLK1, the second clock signal CLK2, and the third clock signal CLK3 supplied to the detection circuit disposed in each of the pixels on the n-th (n is an integer and satisfies 1≦n≦N) row will be called a reset signal RST-n, a first clock signal CLK1-n, a second clock signal CLK2-n, and a third clock signal CLK3-n.

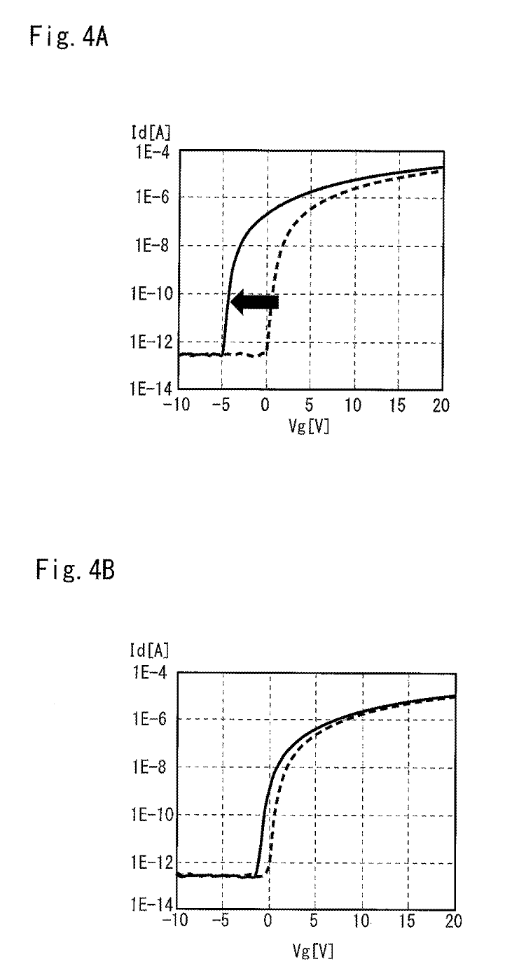

The detection circuit will be described below in terms of its configuration. FIG. 3 is an equivalent circuit diagram of the detection circuit according to the present embodiment. As illustrated in FIG. 3, a detection circuit 120 includes TFTs 121 to 124.

The TFT 121 includes a gate electrode connected to a terminal A2, a drain electrode connected to a terminal A5, and a source electrode connected to a drain electrode of the TFT 122 and a gate electrode of the TFT 123.

The TFT 122 includes a gate electrode and a source electrode connected to a terminal A1, and the drain electrode connected to the source electrode of the TFT 121 and the gate electrode of the TFT 123.

The TFT 123 includes the gate electrode connected to the source electrode of the TFT 121 and the drain electrode of the TFT 122, a drain electrode connected to a terminal A3, and a source electrode connected to a drain electrode of the TFT 124.

The TFT 124 includes a gate electrode connected to a terminal A4, the drain electrode connected to the source electrode of the TFT 123, and a source electrode connected to the signal read line.

The terminal A1 is connected with the first clock signal line to receive the first clock signal CLK1. The terminal A2 is connected with the reset signal line to receive the reset signal RST. The terminal A3 is connected with the third clock signal line to receive the third clock signal CLK3. The terminal A4 is connected with the second clock signal line to receive the second clock signal CLK2. The terminal A5 receives a voltage signal at constant potential (VSS).

The equivalent circuit illustrated in FIG. 3 includes a node Va connected to the source electrode of the TFT 121, the drain electrode of the TFT 122, and the gate electrode of the TFT 123.

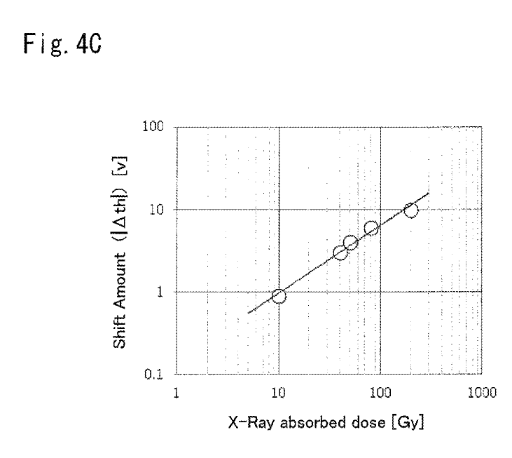

The TFT 122 in the detection circuit 120 has threshold voltage varied in accordance with irradiation time and intensity of X-rays. The TFTs 121, 123, and 124 other than the TFT 122 each have threshold voltage hardly varied irrespective of irradiation time and intensity of X-rays. Specifically, as indicated in FIG. 4A, the TFT 122 has a threshold voltage property indicated by a broken line in a state not irradiated with X-rays and a threshold voltage property indicated by a solid line in a state after X-ray irradiation. Meanwhile, as indicated in FIG. 4B, the TFTs other than the TFT 122 each have a threshold voltage property indicated by a broken line in a state not irradiated with X-rays and a threshold voltage property indicated by a solid line in a state after X-ray irradiation. More specifically, as indicated in FIGS. 4A and 4B, the TFT 122 has the threshold voltage negatively shifted in accordance with X-ray irradiation whereas the TFTs other than the TFT 122 each have the threshold voltage hardly changed by X-ray irradiation. As indicated in FIG. 4C, the threshold voltage of the TFT 122 is negatively shifted by a shift amount |Δth| that increases as an X-ray absorbed dose increases. In other words, the shift amount of the threshold voltage of the TFT 122 increases as an X-ray irradiation dose (irradiation time and intensity) increases.

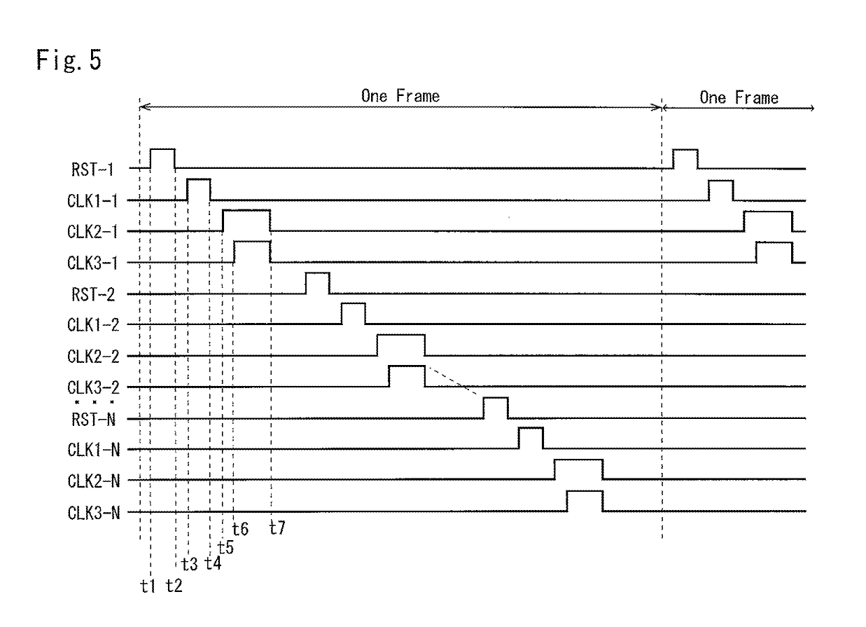

Described next are the control signals supplied to each of the detection circuits 120 and behavior of the detection circuit 120. FIG. 5 is a timing chart of the reset signal RST, the first clock signal CLK1, the second clock signal CLK2, and the third clock signal CLK3 supplied to the detection circuit 120 disposed in each of the pixels on the first to N-th rows in one frame period.

As indicated in FIG. 5, the terminal A2 of a detection circuit 120(1) in each of the pixels on the first row receives a reset signal RST-1 at H-level potential (VDD) between time t1 and time t2. The TFT 121 is then turned ON and the potential at the node Va is reset to VSS by the voltage signal VSS received by the terminal A5. In this case, the gate electrode of the TFT 123 receives the potential at the node Va, and the TFT 123 is kept OFF.

Between time t3 and time t4 after the time t2, the terminal A1 receives a first clock signal CLK1-1 at the H-level potential (VDD). The TFT 122 is then turned ON and the node Va has potential calculated by VDD—threshold voltage (Vth) of the TFT 122. In this case, the gate electrode of the TFT 123 receives the potential (VDD−Vth) at the node Va, and the TFT 123 is turned ON.

At time t5 after the time t4, the terminal A4 subsequently receives a second clock signal CLK2-1 at the H-level potential. At time t6 after the time t5, the terminal A3 receives a third clock signal CLK3-1 at the H-level potential. The potential at a source terminal of the TFT 123 and a drain terminal of the TFT 124 is thus changed in accordance with the potential at the node Va, and a voltage signal indicating the potential at the source terminal of the TFT 123 and the drain terminal of the TFT 124 is transmitted to a data line 112 connected to the source electrode of the TFT 124.

The detection circuit 120 disposed in each of the pixels on the second and subsequent rows receives, after the detection circuit 120 in each of the pixels on the preceding row outputs the voltage signal, control signals similar to the reset signal RST-1, the first clock signal CLK1-1, the second clock signal CLK2-1, and the third clock signal CLK3-1 received by the detection circuit 120(1). The detection circuit 120 disposed in each of the pixels on this row transmits, by the row, to the data line 112, the voltage signal indicating the potential at the source terminal of the TFT 123 and the drain terminal of the TFT 124 according to the potential at the node Va.

The TFT 122 has the threshold voltage negatively shifted by X-ray irradiation. The potential at the node Va is thus changed in accordance with the threshold voltage (Vth) of the TFT 122 between before and after an X-ray irradiation period, and the potential at the source terminal of the TFT 123 and the drain terminal of the TFT 124 is changed accordingly. In the present embodiment, a voltage signal is read out of the detection circuit 120 before and after the period of X-ray application to the detection circuit board 10, and a difference between the read voltage signals is obtained to detect X-rays having been transmitted through each of the pixels. A specific X-ray detection method of the detection device 1 will be described below.

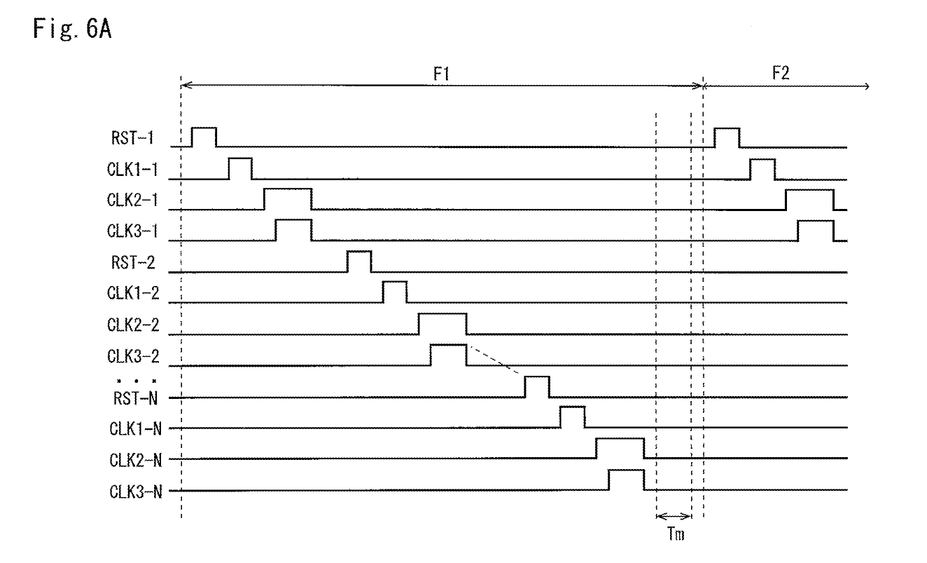

FIG. 6A is a timing chart indicating the X-ray irradiation period of the detection device 1. FIG. 6B is a timing chart indicating change in potential at the node Va of each of the detection circuits 120 between before and after the X-ray irradiation period.

As indicated in FIG. 6A, in a frame period (F1), under the control of the timing controller 203, the driving circuit 201 supplies each of the detection circuits 120 disposed in pixels 100 on the first to N-th rows with the control signals RST and CLK1 to CLK3 by the row. Each of the detection circuits 120 disposed in the pixels 100 on the first to N-th rows thus transmits, to a corresponding one of the data lines 112, a voltage signal before X-ray irradiation.

Specifically, as indicated in FIG. 6B, the gate electrode of the TFT 121 receives the reset signal RST at the H-level potential at time t11, and the potential at the node Va is reset to an L level (VSS). The gate electrode of the TFT 122 then receives the first clock signal CLK1 at the H-level potential at time t12, and the potential at the node Va is changed to (VDD−Vth1). The value Vth1 indicates the threshold voltage of the TFT 122 before X-ray irradiation.

The gate electrode of the TFT 123 then receives the potential at the node Va, and the TFT 123 is turned ON. The drain electrode of the TFT 123 receives the second clock signal CLK2 at the H-level potential at time t13, and the TFT 124 is turned ON. The gate electrode of the TFT 124 receives the third clock signal CLK3 at the H-level potential at time t14, and the potential at the source terminal of the TFT 123 and the drain terminal of the TFT 124 is changed. In a period Tr1 while the TFT 124 is ON, a voltage signal indicating the potential at the source terminal of the TFT 123 and the drain terminal of the TFT 124 is transmitted to the signal read line.

As indicated in FIGS. 6A and 6B, the detection circuit 120 disposed in each of the pixels on the first to N-th rows transmits a voltage signal to a corresponding one of the signal read lines in the frame period (F1), and the light source 30 then emits X-rays under the control of the timing controller 203 in a period Tm in the frame period (F1). X-ray irradiation negatively shifts the threshold voltage of the TFT 122 in each of the detection circuits 120.

Under the control of the timing controller 203, the driving circuit 201 supplies the detection circuit 120 in each of the pixels on the first to N-th rows with the reset signal RST, the first clock signal CLK1, the second clock signal CLK2, and the third clock signal CLK3 in a frame period (F2) as in the frame period (F1). The detection circuit 120 disposed in each of the pixels on the first to N-th rows thus transmits, to the signal read line, a voltage signal after X-ray irradiation.

Specifically, as indicated in FIG. 6B, the gate electrode of the TFT 121 receives the reset signal RST at the H-level potential at time t21, the potential at the node Va is reset to VSS, and the gate electrode of the TFT 122 then receives the first clock signal CLK1 at the H-level potential at time t22. The potential at the node Va is then changed to (VDD−Vth2). The value Vth2 indicates the threshold voltage of the TFT 122 after X-ray irradiation, and satisfies the relation Vth1>Vth2. In other words, the potential at the node Va after X-ray irradiation is larger than the potential at the node Va before X-ray irradiation by the difference (Vth1−Vth2) in threshold voltage of the TFT 122.

The gate electrode of the TFT 123 receives the potential (VDD−Vth2) at the node Va, and the TFT 123 is turned ON. The gate electrode of the TFT 124 receives the third clock signal CLK3 at the H-level potential at time t23, and the TFT 124 is turned ON. The drain electrode of the TFT 123 subsequently receives the third clock signal CLK3 at the H-level potential at time t24, and the potential at the source terminal of the TFT 123 is changed in accordance with the potential at the node Va. In other words, the potential at the source terminal of the TFT 123 is larger than the potential before X-ray irradiation by the difference in potential at the node Va.

In a period Tr2 while the TFT 124 is ON, a voltage signal indicating the potential at the source terminal of the TFT 123 and the drain terminal of the TFT 124 is transmitted to the signal read line. The transmitted voltage signal is larger than that before X-ray irradiation.

The signal reading circuit 202 receives the voltage signals transmitted to the signal read lines before and after X-ray irradiation. The signal reading circuit 202 receives, from the detection circuits 120, the voltage signals in each of the frame periods before and after X-ray irradiation, and transmits, to the image processing device 40, an image signal indicating the difference between the voltage signals in each of the frame periods before and after X-ray irradiation by the pixel. The image processing device 40 generates an X-ray image in accordance with the image signal for each of the pixels transmitted from the signal reading circuit 202.

As described above, the detection circuit 120 includes the TFT 122 having the threshold voltage negatively shifted by X-ray irradiation more easily than the TFTs 121, 123, and 124, to obtain the voltage signals according to change in threshold voltage of the TFT 122 between before and after the X-ray irradiation period. X-rays having been transmitted through the target S can be detected in each of the pixels 100 by obtaining the difference between the voltage signals before and after the X-ray irradiation period in each of the pixels 100.

In a case of subsequently detecting X-rays after X-ray detection, the TFT 122 of each of the detection circuits 120 at the detection circuit board 10 has negatively shifted threshold voltage. In view of this, subsequent X-ray detection can be performed with a new detection circuit board 10. X-rays can alternatively be detected after elapse of a predetermined period necessary for recovery to the original value, of the threshold voltage of the TFT 122 in each of the detection circuits 120.

The TFT 122 and the remaining TFTs 121, 123, and 124 will be described next in terms of their specific structures. The TFTs 121, 123, and 124 are structured identically, and the TFT 121 will thus be exemplarily described below.

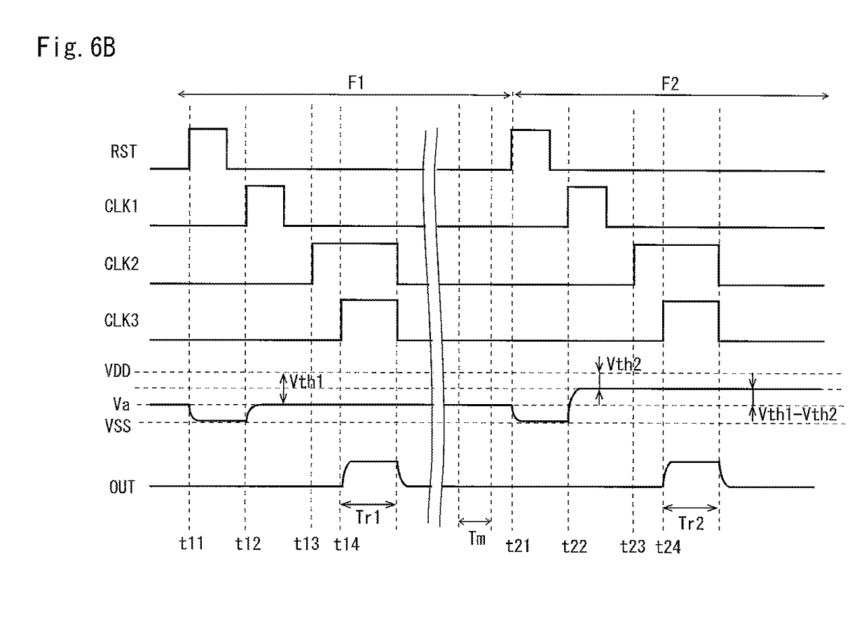

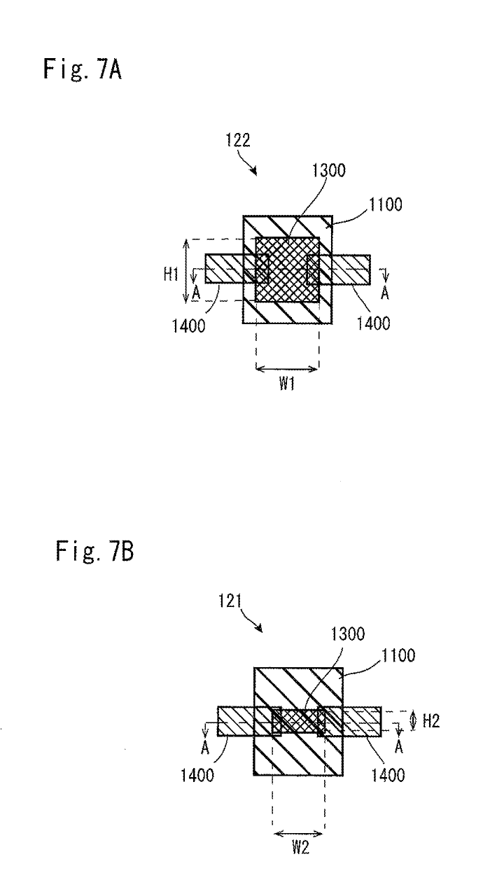

FIG. 7A is a schematic top view of the TFT 122, and FIG. 7B is a schematic top view of the TFT 121. FIG. 8A is a sectional view taken along line A-A, of the TFT 122 illustrated in FIG. 7A, and FIG. 8B is a sectional view taken along line A-A, of the TFT 121 illustrated in FIG. 7B.

In FIGS. 8A and 8B, the TFT 122 and the TFT 121 each include a transmittive substrate 1000 such as a glass plate, a gate layer 1100 provided thereon, and a gate insulating film 1121 covering the gate layer 1100.

Examples of the gate layer 1100 include laminated films of titanium and aluminum, and laminated films of titanium, aluminum, and titanium in the mentioned order. The examples of the gate layer 1100 also include a metal single layer film made of titanium, molybdenum, tantalum, tungsten, copper, or the like, laminated films of any of these metals, and an alloy film containing any of these metals. The gate layer 1100 is formed to provide the gate electrode of each of the TFTs 122 and 121. Example of the gate insulating film 1121 include laminated films of a silicon oxide film and a silicon nitride film.

The gate insulating film 1121 is provided thereon with a semiconductor layer 1300 overlapped with the gate layer 1100. The semiconductor layer 1300 can be made of an oxide semiconductor containing indium, gallium, zinc, and oxygen.

The semiconductor layer 1300 of the TFT 122 according to the present embodiment has an area (W1 x H1) larger than an area (W2 x H2) of the semiconductor layer 1300 of the TFT 121. When the semiconductor layer 1300 of a TFT is irradiated with X-rays, ionization generates paired electrons and electron holes at the interface between the semiconductor layer 1300 and the gate insulating film 1121. The threshold voltage of the TFT is negatively shifted due to electric charges of the paired electrons and electron holes. The larger semiconductor layer 1300 leads to more electric charges by X-ray irradiation and the threshold voltage is negatively shifted more easily. When the semiconductor layers 1300 are formed such that the semiconductor layer 1300 of the TFT 122 is larger in area than the semiconductor layer 1300 of the TFT 121, the threshold voltage of the TFT 122 is varied more easily by X-ray irradiation.

The substrate 1000 is provided thereon with source layers 1400 partially covering the semiconductor layer 1300. Examples of the source layers 1400 include laminated films of titanium, aluminum, and titanium or molybdenum in the mentioned order. The source layers 1400 are formed to provide the source electrode and the drain electrode of each of the TFTs 122 and 121.

There is provided a passivation film 1500 covering the semiconductor layer 1300 and the source layers 1400, and the passivation film 1500 is provided thereon with a flattening film 1600. Examples of the passivation film 1500 include a silicon oxide film, a silicon nitride film, and a silicon oxinitride film, as well as laminated films thereof. The flattening film 1600 is made of a photosensitive resin material or the like.

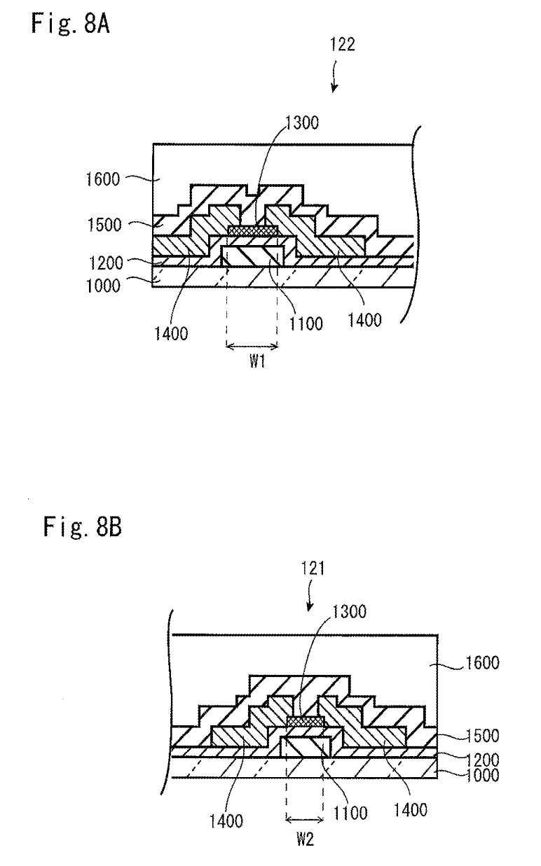

A method of producing the detection circuit board 10 according to the present embodiment will be described next with reference to FIGS. 9A to 9F.

As illustrated in FIG. 9A, titanium, aluminum, and titanium are initially deposited in the mentioned order on one of the surfaces of the substrate 1000 in accordance with the sputtering method or the like to form the gate layer 1100. The gate layer 1100 is then patterned in accordance with the photolithography method. The gate electrodes of the TFTs are thus formed.

As illustrated in FIG. 9B, a silicon oxide film and a silicon nitride film covering the gate layers 1100 are subsequently deposited in the mentioned order in accordance with the plasma CVD method or the like to form the gate insulating film 1121.

As illustrated in FIG. 9C, the semiconductor layer 1300 containing indium, gallium, zinc, and oxygen is then deposited on the gate insulating film 1121 in accordance with the sputtering method or the like. The semiconductor layer 1300 contains indium, gallium, and zinc at the ratios of 1:1:1, for example. The semiconductor layer 1300 is patterned in accordance with the photolithography method to provide the semiconductor layers 1300 overlapped with the gate electrodes 1100 of the TFTs. The semiconductor layer 1300 at the position of the TFT 122 is patterned to be larger in area than the semiconductor layer 1300 at the position of the TFT 121.

As illustrated in FIG. 9D, titanium, aluminum, and titanium or molybdenum are then deposited in the mentioned order in accordance with the sputtering method or the like and are patterned in accordance with the photolithography method. The source layers 1400 (the source electrode and the drain electrode) are thus provided in contact with part of the semiconductor layer 1300 of each of the TFTs 122 and 121.

As illustrated in FIG. 9E, a silicon oxide film is subsequently deposited in accordance with the plasma CVD method or the like to form the passivation film 1500. As illustrated in FIG. 9F, a photosensitive resin is deposited on the passivation film 1500 to provide the flattening film 1600.

In the first embodiment described above, the detection circuits 120 each include the TFT 122 having the threshold voltage easily shifted by X-ray irradiation, and the TFTs 121, 123, and 124 having the threshold voltage hardly shifted. X-rays having been transmitted through the pixels provided with the detection circuits 120 are detected by acquiring the voltage signals outputted from the detection circuits 120 before and after the X-ray irradiation period and obtaining the difference between the voltage signals before and after X-ray irradiation for each of the detection circuits 120. Such a configuration eliminates a step of forming a scintillator and a photodiode in the process of producing the detection device 1 and achieves reduction in cost and time for production in comparison to the case of detecting X-rays with use of the scintillator and the photodiode. The first embodiment does not need any scintillator, and thus achieves an appropriate X-ray image with no deterioration in spatial resolution due to scattered scintillation light.

### Second Embodiment

The first embodiment exemplifies the configuration in which the semiconductor layer 1300 of the TFT 122 is larger in area than the semiconductor layers 1300 of the remaining TFTs 121, 123, and 124 in the detection circuit 120. The present invention is also applicable to the following configuration.

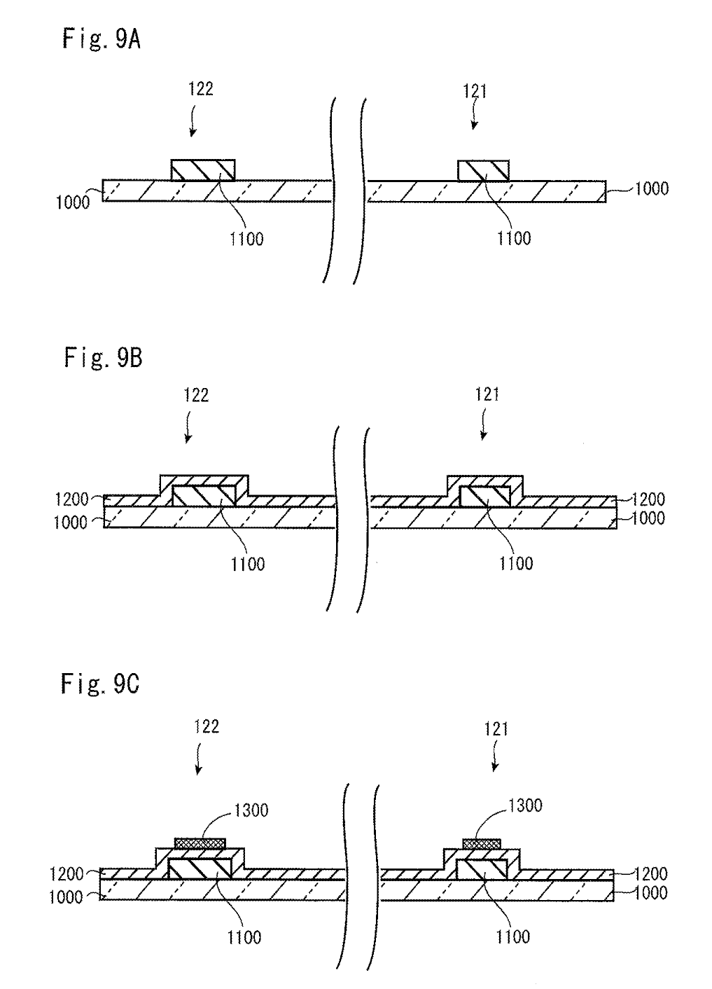

FIG. 10A is a sectional view illustrating a configuration of the TFT 122 according to the present embodiment, and FIG. 10B is a sectional view illustrating a configuration of the TFT 121 according to the present embodiment. In FIGS. 10A and 10B, the configurations similar to those of the first embodiment are denoted by reference signs identical to those of the first embodiment.

Ionization of X-rays applied to a TFT causes storage of electric charges (electron holes) in an oxide film included in a gate insulating film and change in threshold voltage of the TFT. As the gate insulating film 1121 is thicker, electric charges (electron holes) are stored more easily in the gate insulating film by X-ray irradiation and the threshold voltage is negatively shifted more easily. As illustrated in FIG. 10A, the gate insulating film 1121 according to the present embodiment has a thickness hl at the position on the gate electrode 1100 in the TFT 122, larger than a thickness h2 at the position on the gate electrode 1100 in the TFT 121 illustrated in FIG. 10B. The oxide film in the gate insulating film 1121 is thicker in the TFT 122 than in the TFT 121 (not illustrated).

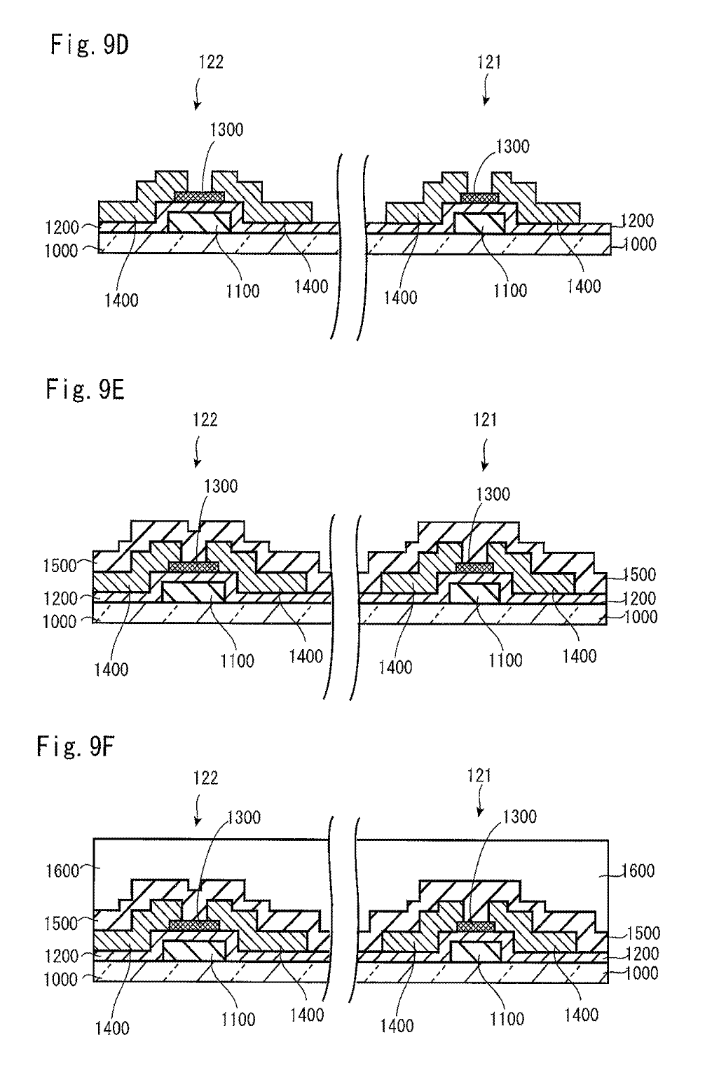

In this case, similarly to the first embodiment, after the gate layers 1100 are formed as in FIG. 9A, the gate insulating film 1121 covering the gate electrodes 1100 is deposited as illustrated in FIG. 11A. As illustrated in FIG. 11B, the gate insulating film 1121 is subsequently patterned with use of a halftone mask or the like so that the thickness h2 at the position of the TFT 121 is smaller than the thickness h1 at the position of the TFT 122. The TFTs 122 and 121 illustrated in FIGS. 10A and 10B can be formed by subsequently executing steps similar to those illustrated in FIGS. 9C to 9F.

As described above, the gate insulating film 1121 according to the second embodiment has the thickness at the position on the gate electrode 1100 of the TFT 122 larger than the thickness at the position on the gate electrodes 1100 of the TFTs 121, 123, and 124 in the detection circuit 120. The oxide film included in the gate insulating film 1121 is thicker in the TFT 122 than in the TFTs 121, 123, and 124. X-ray irradiation thus achieves easier negative shift of the threshold voltage of the TFT 122 than the threshold voltage of the TFTs 121, 123, and 124. X-rays at the pixel provided with the detection circuit 120 can be detected by obtaining the difference between the voltage signals outputted from the detection circuit 120 before and after the X-ray irradiation period and corresponding to the threshold voltage of the TFT 122.

### Modification Examples

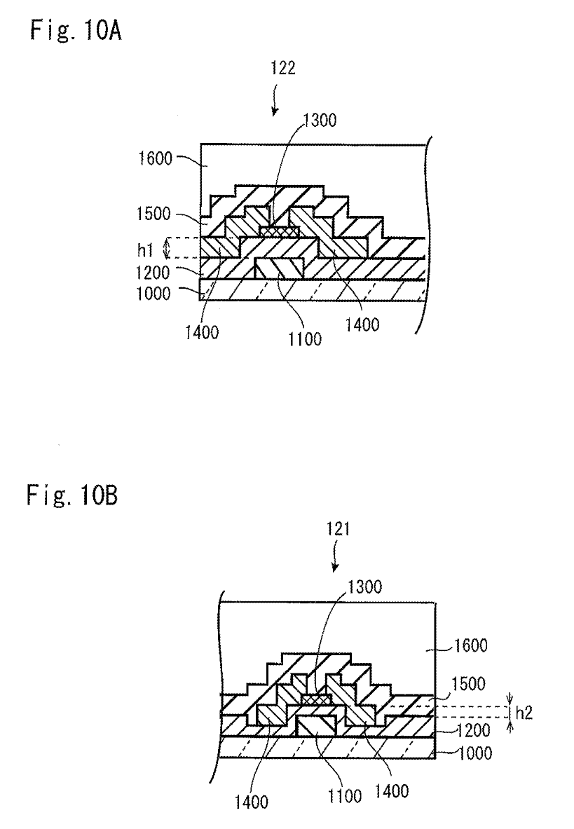

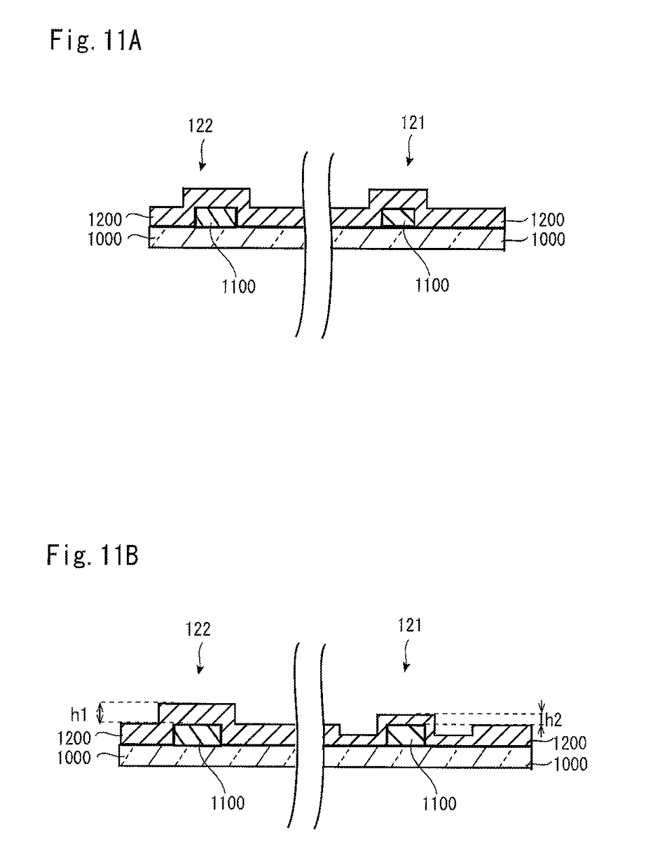

The embodiments of the present invention described above are merely exemplified to implement the present invention. The present invention should not be limited to the above embodiments, and can be implemented with appropriate modifications to the above embodiments without departing from the spirit of the present invention. Modification examples of the present invention will be described below.
(1) In the first embodiment, the semiconductor layer 1300 of the TFT 122 can alternatively be made thicker than the semiconductor layers 1300 of the TFTs 121, 123, and 124 in the detection circuit 120. The thicker semiconductor layer 1300 has more electric charges (electron holes) due to ionization caused by X-ray irradiation. The threshold voltage of a TFT is thus negatively shifted more easily. This configuration can thus cause the threshold voltage of the TFT 122 to be negatively shifted by X-ray irradiation and cause the threshold voltage of the TFTs 121, 123, and 124 to be hardly varied by X-ray irradiation. The present modification example also achieves detection of X-rays having been transmitted through each of the pixels by obtaining the difference between the voltage signals outputted from the corresponding one of the detection circuits 120 before and after the X-ray irradiation period.
(2) In the detection circuit 120 according to the first embodiment, the TFT 122 can alternatively be made larger in channel length than the TFTs 121, 123, and 124. As indicated in FIG. 12, the larger channel length leads to a larger shift amount ΔVth of the threshold voltage of the TFT negatively shifted by X-ray irradiation. This configuration thus achieves negative shift of the threshold voltage of the TFT 122 by X-ray irradiation. The present modification example also achieves detection of X-rays having been transmitted through each of the pixels by obtaining the difference between the voltage signals outputted from the corresponding one of the detection circuits 120 before and after the X-ray irradiation period.
(3) Positive fixed electric charges are stored easily in an oxide film by ionization of X-rays. A TFT containing low-temperature polysilicon includes an oxide film in a gate insulating film and is thus easily influenced by X-rays. A TFT containing amorphous silicon includes a gate insulating film typically configured by a nitride film and is thus hardly influenced by X-rays. A TFT containing an oxide semiconductor includes a gate insulating film typically having a lamination structure of an oxide film and a nitride film. The TFT can thus be made hardly or easily influenced by X-rays through adjustment of the thickness of the oxide film. The detection circuit 120 according to the first embodiment can alternatively include the TFT 122 made of low-temperature polysilicon, and the TFTs 121, 123, and 124 made of an oxide semiconductor as in the first embodiment. Still alternatively, the semiconductor layer 1300 of the TFT 122 can be made of an oxide semiconductor and the semiconductor layers 1300 of the TFTs 121, 123, and 124 can be made of amorphous silicon.
(4) The TFT 122 and the TFTs 121, 123, and 124 in the detection circuit 120 can have configurations obtained by combining any of the configurations according to the first and second embodiments and the modification examples (1) to (3).
(5) The first embodiment exemplifies the detection circuits 120 illustrated in FIG. 3 disposed at the detection circuit board 10. The detection circuits 120 can be replaced with detection circuits 220 illustrated in FIG. 13.

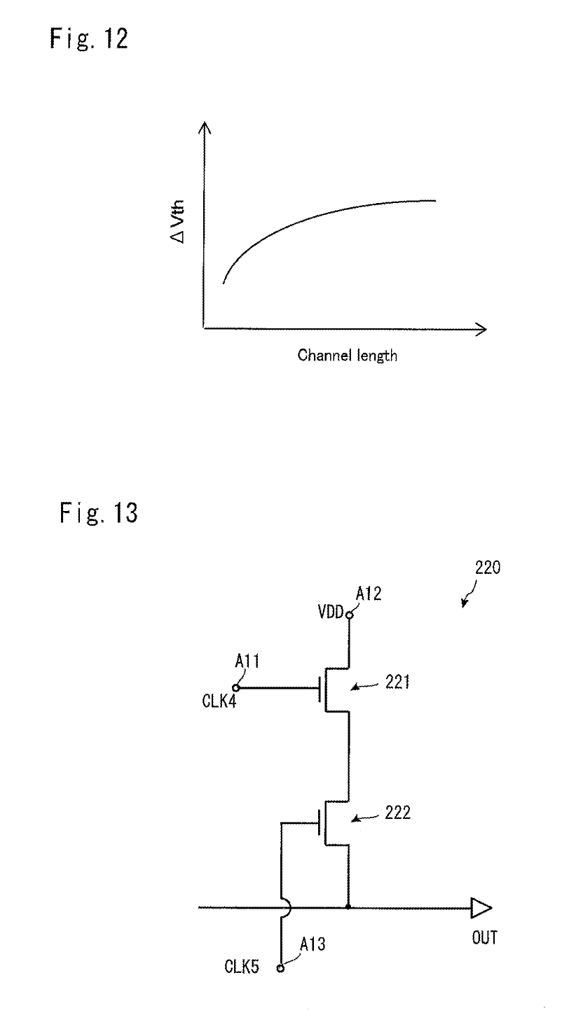

FIG. 14 is a schematic diagram of a detection circuit board 10a, a driving circuit 201a, and the signal reading circuit 202 according to the present modification example. According to the present modification example, the detection circuit board 10a is provided with a plurality of detection circuits 220. Each of the detection circuits 220 at the detection circuit board 10a according to this example is connected with two driving lines in total, namely, a fourth clock signal line for receipt of a fourth clock signal CLK4 from the driving circuit 201a and a fifth clock signal line for receipt of a fifth clock signal CLK5 from the driving circuit 201a.

The detection circuit 220 will be described next in terms of its configuration. As illustrated in FIG. 13, the detection circuit 220 includes TFTs 221 and 222. Similarly to the TFT 122, the TFT 221 according to this example has threshold voltage negatively shifted by X-ray irradiation. Similarly to the TFTs 121, 123, and 124, the TFT 222 has threshold voltage hardly changed by X-ray irradiation.

The TFT 221 includes a gate electrode connected to a terminal A11, a drain electrode connected to a terminal A12, and a source electrode connected to a drain electrode of the TFT 222.

The TFT 222 includes a gate electrode connected to a terminal A13, the drain electrode connected to the source electrode of the TFT 221, and a source electrode connected to a signal read line.

The terminal A11 is connected with the fourth clock signal line to receive the fourth clock signal CLK4 from the driving circuit 201a. The terminal A13 is connected with the fifth clock signal line to receive the fifth clock signal CLK5 from the driving circuit 201a. The terminal Al2 receives a voltage signal at constant potential (VSS).

When the gate electrode of the TFT 221 receives the fourth clock signal CLK4 at the H-level potential, the TFT 221 is turned ON and current according to the threshold voltage of the TFT 221 flows to a source terminal of the TFT 221. When the gate electrode of the TFT 222 receives the fifth clock signal CLKS at the H-level potential, the TFT 222 is turned ON and a signal according to a current value at the source terminal of the TFT 221 is transmitted to the signal read line.

X-rays are detected with the detection circuit 220 in accordance with a method similar to that according to the first embodiment. X-rays having been transmitted through each of the pixels are detected by obtaining a difference between signals outputted from a corresponding one of the detection circuits 220 before and after X-ray irradiation.

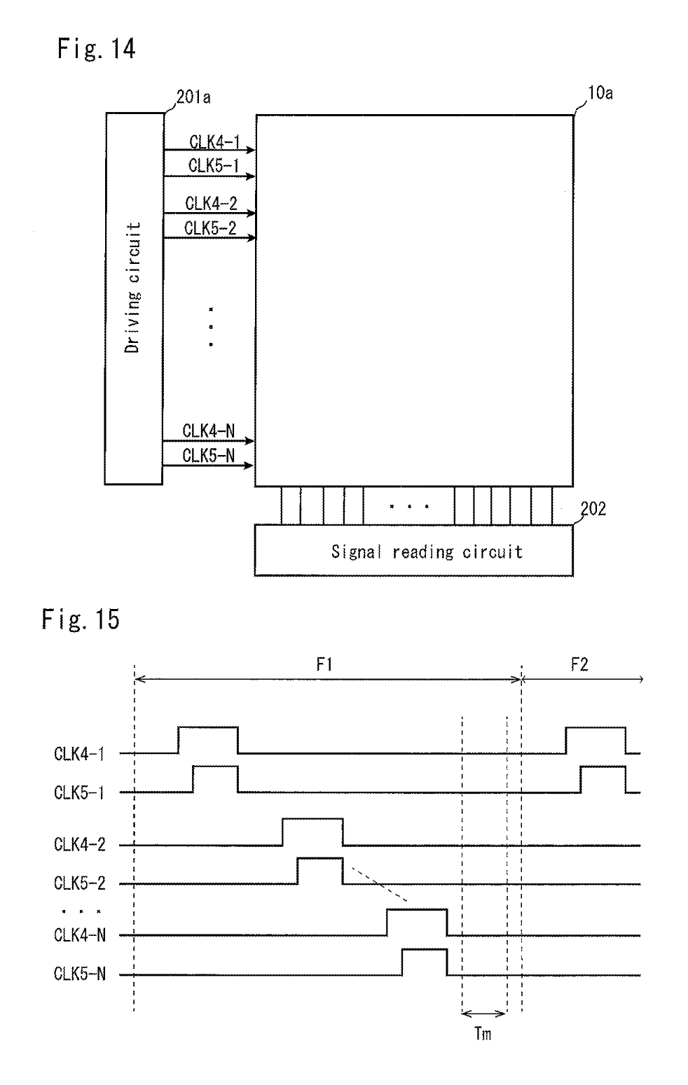

As indicated in FIG. 15, in the frame period (F1), under the control of the timing controller 203, the driving circuit 201a supplies each of the detection circuits 220 disposed in the pixels on the first to N-th rows with the fourth clock signal CLK4 and the fifth clock signal CLK5 by the row. Each of the detection circuits 220 disposed in the pixels on the first to N-th rows thus transmits, to a corresponding one of the signal read lines, a signal according to current at the source terminal of the TFT 221 before X-ray irradiation.

The detection circuit 220 disposed in each of the pixels on the first to N-th rows transmits a voltage signal to the corresponding one of the signal read lines in the frame period (F1), and the light source 30 then emits X-rays under the control of the timing controller 203 in the period Tm in the frame period (F1). This negatively shifts the threshold voltage of the TFT 221 in each of the detection circuits 220.

Subsequently in the frame period (F2), similarly to the frame period (F1), the driving circuit 201a supplies each of the detection circuits 220 disposed in the pixels on the first to N-th rows with the fourth clock signal CLK4 and the fifth clock signal CLK5 by the row. Each of the detection circuits 220 disposed in the pixels on the first to N-th rows thus transmits, to the corresponding one of the signal read lines, a signal according to current at the source terminal of the TFT 221 after X-ray irradiation.

The signal outputted from the detection circuit 220 is changed in accordance with the threshold voltage of the TFT 221. X-rays having been transmitted through each of the pixels can thus be detected by obtaining the difference between the signals outputted from a corresponding one of the detection circuits 220 before and after the X-ray irradiation period.

The TFTs 221 and 222 according to the present modification example can be structured identically with the TFTs 122 and 121 according to any one of the first and second embodiments and the modification examples (1) to (3), or can have structures obtained by combining any of the structures according to the first and second embodiments and the modification examples (1) to (3).
(6) The embodiments and the modification examples exemplify irradiation of X-rays as radial rays emitted from the light source 30. The present invention is also applicable to irradiation of radial rays other than X-rays.

1. A detection device comprising:
an irradiation unit configured to emit radial rays;
a driving unit configured to output a control signal;
a detection circuit configured to output a signal according to the control signal; and
a signal processor configured to acquire the signal outputted from the detection circuit; wherein
the detection circuit includes a detection thin film transistor having threshold voltage varied in accordance with irradiation of the radial rays, and
the signal processor outputs a difference between a signal outputted from the detection circuit in accordance with a control signal supplied before irradiation of the radial rays and a signal outputted from the detection circuit in accordance with a control signal supplied after irradiation of the radial rays.

2. The detection device according to claim 1, wherein the radial rays are X-rays.

3. The detection device according to claim 1, wherein
the detection circuit further includes a driving thin film transistor having threshold voltage varied by irradiation of the radial rays more slightly than the detection thin film transistor,
the detection thin film transistor and the driving thin film transistor each include a semiconductor layer, and
the semiconductor layer in the detection thin film transistor is larger in area than the semiconductor layer in the driving thin film transistor.

4. The detection device according to claim 1, wherein
the detection circuit further includes a driving thin film transistor having threshold voltage varied by irradiation of the radial rays more slightly than the detection thin film transistor,
the detection thin film transistor and the driving thin film transistor each include
a gate electrode,
an insulating film covering the gate electrode and including an oxide film, and
a semiconductor layer provided on the insulating film, and
the oxide film included in the insulating film of the detection thin film transistor is thicker than the oxide film included in the insulating film of the driving thin film transistor.

5. The detection device according to claim 1, wherein
the detection circuit further includes a driving thin film transistor having threshold voltage varied by irradiation of the radial rays more slightly than the detection thin film transistor,
the detection thin film transistor and the driving thin film transistor each include a semiconductor layer, and
the semiconductor layer in the detection thin film transistor is thicker than the semiconductor layer in a thin film transistor other than the detection thin film transistor.

6. The detection device according to claim 1, wherein
the detection circuit further includes a driving thin film transistor having threshold voltage varied by irradiation of the radial rays more slightly than the detection thin film transistor, and
the detection thin film transistor is larger in channel length than the driving thin film transistor.

7. The detection device according to claim 1, wherein
the detection circuit further includes a driving thin film transistor having threshold voltage varied by irradiation of the radial rays more slightly than the detection thin film transistor, and
the detection thin film transistor includes a semiconductor layer containing low-temperature polysilicon, and the driving thin film transistor includes a semiconductor layer containing an oxide.
